(19) United States
(12) Patent Application Publication
(10) Pub. No.: US 2025/0149861 A1
(43) Pub. Date: May 8, 2025

(54) OXIDE-CONFINED SEMICONDUCTOR LASER HAVING HIGH ALUMINUM CONTENT AND METHOD OF FABRICATING THE SAME

(71) Applicant: INSTITUTE OF SEMICONDUCTORS, CHINESE ACADEMY OF SCIENCES, Beijing (CN)

(72) Inventors: Wanhua Zheng, Beijing (CN); Liang Wang, Beijing (CN); Xuyan Zhou, Beijing (CN); Hongwei Qu, Beijing (CN); Fansheng Meng, Beijing (CN); Aiyi Qi, Beijing (CN); Chuanwang Xu, Beijing (CN); Renbo Han, Beijing (CN); Yufei Wang, Beijing (CN)

(21) Appl. No.: 18/726,135

(22) PCT Filed: Jan. 5, 2024
(86) PCT No.: PCT/CN2024/070862

§ 371 Date: Jul. 2, 2024

(30) Foreign Application Priority Data
Nov. 14, 2022 (CN) 202211429937.1

(51) Int. Cl. H01S 5/22; H01S 5/026; H01S 5/20

(52) U.S. Cl. CPC H01S 5/22; H01S 5/026; H01S 5/2018

(57) ABSTRACT

The present disclosure provides an oxide-confined semiconductor laser having high aluminum content and a fabricating method. The semiconductor laser includes: an N-side metal electrode, an N-type GaAs substrate, an N-type confinement layer, an N-type waveguide layer, an active region, a P-type waveguide layer, a P-type confinement layer, a P-type high aluminum content layer, a P-type contact layer, and a P-side metal electrode. The P-type high aluminum content layer and the P-type contact layer are etched to form a ridge structure. The P-type high aluminum content layer is oxidized to form an oxidation confinement layer. The oxidation confinement layer is between an upper surface of the P-type confinement layer and a lower surface of the P-type contact layer, and covers both sides of the ridge structure, so as to form a current injection channel below the ridge structure and an electrical isolation on the both sides of the ridge structure.

### CROSS REFERENCE TO RELATED APPLICATION

This application is a Section 371 National Stage Application of International Application No. PCT/CN2024/070862, filed on Jan. 5, 2024, entitled “OXIDE-CONFINED SEMICONDUCTOR LASER HAVING HIGH ALUMINUM CONTENT AND METHOD OF FABRICATING THE SAME”, which claims priority to Chinese Patent Application No. 202211429937.1 filed on Nov. 14, 2022, the contents of which are incorporated herein by reference in their entireties.

### TECHNICAL FIELD

The present disclosure relates to the field of semiconductor laser technology, and in particular to an oxide-confined semiconductor laser having high aluminum content and a method of fabricating the same.

### BACKGROUND

Nowadays, semiconductor lasers as pump sources account for one-third to one-half of a total cost of solid-state lasers, and one-half to two-thirds of a total cost of fiber lasers. Therefore, in order to reduce industrial costs, obtaining high-power, high-efficiency and high-reliability semiconductor lasers is crucial to the entire laser industry, and reducing light loss and resistance may effectively improve the performance of semiconductor lasers.

It is mentioned in relevant literature that in an epitaxial structure of a traditional GaAs-based semiconductor laser, a loss and a resistance generated by a P-type epitaxial layer respectively account for 46% and 91% of the total because a light loss caused by free holes is about three times that of free electrons and a hole mobility is much less than an electron mobility. Therefore, commonly used epitaxial structures are asymmetric structures to reduce a P-side light field distribution and reduce a thickness of P-type region, so as to reduce the loss and the resistance. However, the thickness may not be further reduced when reaching a certain level, mainly because that thinning a P-type waveguide layer may result in a lower confinement factor and that a too thin P-type confinement layer may cause a leakage of light field to a highly doped contact layer, which may result in more losses.

In addition, at present, when fabricating a semiconductor laser, it is generally needed to grow an insulating material such as SiO₂ or SiₓN_{y} for an electrical isolation, and then form an electrical injection window on a ridge through secondary photolithography and etching processes. However, the growth of insulating material may inevitably introduce defects such as pores and large stresses at an interface. Furthermore, in order to ensure a good sidewall coverage, a thickness of an insulating layer is generally greater than 200 nm, but an excessively thick insulating layer may deteriorate heat dissipation characteristics of the semiconductor laser and reduce the performance and life of semiconductor. Moreover, the secondary photolithography and etching during the formation of electrical injection window may also cause inevitable contamination to the epitaxial wafer, and the secondary photolithography has a small tolerance, which may cause a high failure rate especially for a narrow-strip laser.

### SUMMARY

The present disclosure provides an oxide-confined semiconductor laser having high aluminum content and a method of fabricating the same.

In a first aspect of the embodiments of the present disclosure, an oxide-confined semiconductor laser having high aluminum content is provided, which sequentially includes, from bottom to top: an N-side metal electrode 1, an N-type GaAs substrate 2, an N-type confinement layer 3, an N-type waveguide layer 4, an active region 5, a P-type waveguide layer 6, a P-type confinement layer 7, a P-type high aluminum content layer 8, a P-type contact layer 9, and a P-side metal electrode 10, where the P-type high aluminum content layer 8 and the P-type contact layer 9 are etched to form a ridge structure; where the P-type high aluminum content layer 8 is oxidized to form an oxidation confinement layer 81; and where the oxidation confinement layer 81 is located between an upper surface of the P-type confinement layer 7 and a lower surface of the P-type contact layer 9, and covers both sides of the ridge structure, so as to form a current injection channel below the ridge structure and an electrical isolation on the both sides of the ridge structure.

According to the embodiments of the present disclosure, the P-type high aluminum content layer 8 is made of AlₓGaAs, and 0.8≤x≤1.

According to the embodiments of the present disclosure, the oxidation confinement layer 81 is made of Al₂O₃.

According to the embodiments of the present disclosure, a width of the ridge structure is in a range of 1 μm to 1000 μm.

According to the embodiments of the present disclosure, a thickness of the P-type high aluminum content layer 8 is in a range of 10 nm to 500 nm.

According to the embodiments of the present disclosure, a P-type doping concentration in the P-type high aluminum content layer 8 is in a range of 1E17 cm⁻³ to 1E20 cm⁻³.

According to the embodiments of the present disclosure, a front cavity surface of the oxide-confined semiconductor laser having high aluminum content is coated with an anti-reflection film having a reflectivity less than or equal to 50%, and a rear cavity surface of the oxide-confined semiconductor laser having high aluminum content is coated with a high-reflection film having a reflectivity greater than or equal to 80%.

According to the embodiments of the present disclosure, the active region 5 includes a quantum well, a quantum dot, or a superlattice structure.

According to the embodiments of the present disclosure, each of the N-type confinement layer 3, the N-type waveguide layer 4, the P-type waveguide layer 6 and the P-type confinement layer 7 is made of AlₓGaAs; and each of the N-type confinement layer 3, the N-type waveguide layer 4, the P-type waveguide layer 6 and the P-type confinement layer 7 has a uniform Al content, an Al content gradually varying from 5% to 80%, or an Al content varying periodically.

In a second aspect of the embodiments of the present disclosure, a method of fabricating an oxide-confined semiconductor laser having high aluminum content is provided, including: epitaxially growing, on the N-type GaAs substrate layer 2, the N-type confinement layer 3, the N-type waveguide layer 4, the active region 5, the P-type waveguide layer 6, the P-type confinement layer 7, the P-type high aluminum content layer 8 and the P-type contact layer 9 sequentially; forming a photoresist mask on the P-type contact layer 9; etching the P-type high aluminum content layer 8 and the P-type contact layer 9 using an etching process to form the ridge structure; oxidizing, after removing the photoresist mask, the P-type high aluminum content layer 8 using an oxidation process to form the oxidation confinement layer 81; fabricating the P-side metal electrode 10 on the P-type contact layer 9, and fabricating the N-side metal electrode 1 below the N-type GaAs substrate layer 2; and performing a chip cleavage, a cavity surface coating and a chip packaging to complete a device fabrication.

### BRIEF DESCRIPTION OF THE DRAWINGS

The above and other objectives, features and advantages of the present disclosure will be more apparent through the following description of embodiments of the present disclosure with reference to the accompanying drawings. In the accompanying drawings:

FIG. 1 schematically shows a structural diagram of an epitaxial structure of an oxide-confined semiconductor laser having high aluminum content provided in the embodiments of the present disclosure;

FIG. 2 schematically shows a structural diagram of an oxide-confined semiconductor laser having high aluminum content, after a formation of a ridge through photolithography and etching, provided in the embodiments of the present disclosure;

FIG. 3 schematically shows a structural diagram of a fabricated oxide-confined semiconductor laser having high aluminum content according to the embodiments of the present disclosure;

FIG. 4 schematically shows a schematic diagram of a refractive index distribution and a fundamental mode field distribution of each layer of a first oxide-confined semiconductor laser having high aluminum content provided in the embodiments of the present disclosure;

FIG. 5 schematically shows a schematic diagram of a refractive index distribution and a fundamental mode field distribution of each layer of a second oxide-confined semiconductor laser having high aluminum content provided in the embodiments of the present disclosure;

FIG. 6 schematically shows a schematic diagram of a refractive index distribution and a fundamental mode field distribution of each layer of a third oxide-confined semiconductor laser having high aluminum content provided in the embodiments of the present disclosure;

FIG. 7 schematically shows a SEM image of an oxidation test result of an oxide-confined semiconductor laser having high aluminum content provided in the embodiments of the present disclosure; and

FIG. 8 schematically shows a device performance comparison of an oxide-confined semiconductor laser having high aluminum content fabricated by an oxidation process according to the embodiments of the present disclosure, a semiconductor laser having high aluminum content fabricated by a conventional process, and an ordinary semiconductor laser fabricated by a conventional process.

### REFERENCE NUMERALS

1: N-side metal electrode; 2: N-type GaAs substrate; 3: N-type confinement layer; 4: N-type waveguide layer; 5: active region; 6: P-type waveguide layer; 7: P-type confinement layer; 8: P-type high aluminum content layer; 81: oxidation confinement layer; 9: P-type contact layer; 10: P-side metal electrode.

### DETAILED DESCRIPTION OF EMBODIMENTS

In order to make the objectives, technical solutions and advantages of the present disclosure more clearly understood, the present disclosure will be further described in detail below in conjunction with specific embodiments and with reference to the accompanying drawings. Obviously, the described embodiments are just some embodiments rather than all embodiments of the present disclosure. Based on the embodiments of the present disclosure, all additional embodiments obtained by those ordinary skilled in the art without carrying out inventive efforts fall within the scope of protection of the present disclosure.

Terms are used herein for the purpose of describing specific embodiments only and are not intended to limit the present disclosure. The terms “including”, “containing”, etc. used herein indicate the presence of the feature, step, operation and/or component, but do not exclude the presence or addition of one or more other features, steps, operations or components.

In the present disclosure, unless otherwise specified and defined, the terms “installation”, “interconnection”, “connection”, “fixation” and other terms should be understood broadly. For example, those terms may refer to a fixed connection, a detachable connection, or an integrated connection, may refer to a mechanical connection, an electrical connection, or communicatively connection with each other, may refer to a direct connection or an indirect connection through an intermediate medium, and may refer to an internal connection of two components or an interaction relationship between two components. For those ordinary skilled in the art, the specific meanings of the above terms in the present disclosure may be understood according to specific cases.

In the description of the present disclosure, it should be understood that the terms “longitudinal”, “length”, “circumferential”, “front”, “rear”, “left”, “right”, “top”, “bottom”, “inside”, “outside”, etc. are used to indicate orientations or positional relationships shown based on the accompanying drawings, which is intended to facilitate and simplify the description of the present disclosure and not to indicate or imply that the sub-system or element referred to must have a specific orientation or must be constructed or operated in a specific orientation, and therefore may not be understood as limitations to the present disclosure.

Throughout the accompanying drawings, the same elements are represented by the same or similar reference numerals. When it is possible to cause confusions in the understanding of the present disclosure, conventional structures or configurations will be omitted. It should be noted that the shapes, sizes and positional relationships of components in the drawings do not reflect the actual sizes, ratios and positional relationships. In addition, in the present disclosure, any reference symbols placed between parentheses should not be constructed as limitations to the present disclosure.

Similarly, in order to condense the present disclosure and help understand one or more of various aspects of the present disclosure, in the above description of exemplary embodiments of the present disclosure, various features of the present disclosure are sometimes grouped together into a single embodiment, figure, or description thereof. References to the terms “an embodiment”, “some embodiments”, “an example”, “specific example”, or “some examples” are intended to include the specific features, structures, materials or characteristics described in the embodiment(s) or example(s) in at least one embodiment or example of the present disclosure. In the specification, the schematic expressions of the above terms may not necessarily refer to the same embodiments or examples. Moreover, the specific features, structures, materials or characteristics described may be combined in an appropriate manner in any one or more embodiments or examples.

In addition, the terms “first”, “second” are used for descriptive purposes only and should not be understood as indicating or implying relative importance or implying the number of technical features indicated. Therefore, a feature defined by “first” or “second” may explicitly or implicitly include one or more such features. In the description of the present disclosure, “a plurality” means at least two, such as two, three, etc., unless otherwise specified.

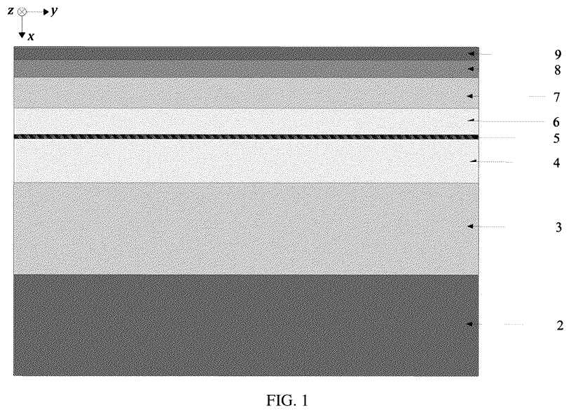

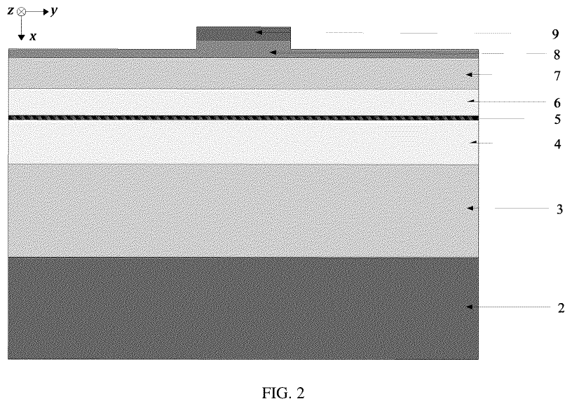

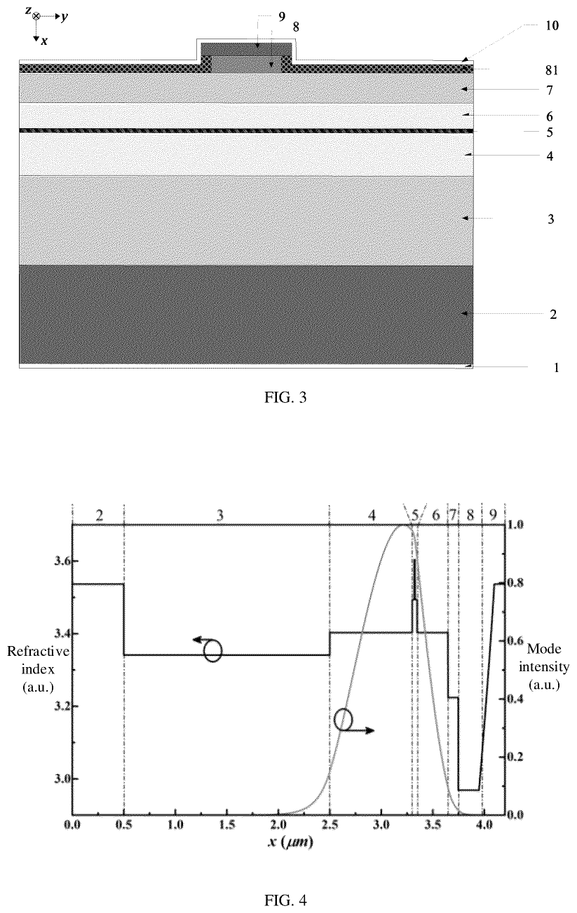

In a first embodiment of the present disclosure, an oxide-confined semiconductor laser having high aluminum content is provided, as shown in FIG. 1, FIG. 2 and FIG. 3, which may sequentially include from bottom to top: an N-side metal electrode 1 forming an ohmic contact with an N-type GaAs substrate 2 to provide an electrical injection for the laser; an N-type GaAs substrate 2 used to support a growth of an epitaxial material; an N-type confinement layer 3 used to control an expansion of a light field in an N-type region; an N-type waveguide layer 4 used to localize the light field in the N-type region; an active region 5; a P-type waveguide layer 6 used to localize a light field in a P-type region; a P-type confinement layer 7 used to control an expansion of the light field in the P-type region; a P-type high aluminum content layer 8 used to compensate for the thinned P-type confinement layer 7 and also used to form an oxidation confinement layer 81; a P-type contact layer 9 used to form an ohmic contact with a metal; and a P-side metal electrode 10. The P-type high aluminum content layer 8 and the P-type contact layer 9 are etched to form a ridge structure. The P-type high aluminum content layer 8 is oxidized to form an oxidation confinement layer 81. The oxidation confinement layer 81 is located between an upper surface of the P-type confinement layer 7 and a lower surface of the P-type contact layer 9, and covers both sides of the ridge structure, so as to form a current injection channel below the ridge structure and an electrical isolation on the both sides of the ridge structure.

On the basis of the above-mentioned embodiments, the P-type high aluminum content layer 8 is made of AlₓGaAs, where 0.8≤x≤1.

On the basis of the above-mentioned embodiments, the oxidation confinement layer 81 is made of Al₂O₃.

On the basis of the above-mentioned embodiments, a width of the ridge structure is in a range of 1 μm to 1000 μm.

On the basis of the above-mentioned embodiments, a thickness of the P-type high aluminum content layer 8 is in a range of 10 nm to 500 nm.

On the basis of the above-mentioned embodiments, a P-type doping concentration in the P-type high aluminum content layer 8 is in a range of 1E17 cm⁻³ to 1E20 cm⁻³.

On the basis of the above-mentioned embodiments, a front cavity surface of the oxide-confined semiconductor laser having high aluminum content is coated with an anti-reflection film having a reflectivity less than or equal to 50%, and a rear cavity surface of the oxide-confined semiconductor laser having high aluminum content is coated with a high-reflection film having a reflectivity greater than or equal to 80%.

On the basis of the above embodiments, the active region 5 includes a quantum well, a quantum dot, or a superlattice structure.

On the basis of the above embodiments, each of the N-type confinement layer 3, the N-type waveguide layer 4, the P-type waveguide layer 6 and the P-type confinement layer 7 may be made of a single material, gradually changing materials, or a variety of periodically or quasi-periodically distributed materials.

In this structure, the P-side high aluminum content layer may further confine the P-side light field expansion. Compared with a traditional semiconductor laser, this structure has a stronger light field confinement capability and a thinner P-side epitaxial layer, which has advantages of reducing internal loss, reducing series resistance, improving heat dissipation, and improving power and efficiency.

In this structure, the oxidation confinement layer 81 formed by the oxidation process has dual functions of forming an electric injection channel and forming an electrical isolation, and the secondary photolithography and additional growth of insulating material are not required, so that the process may be simplified.

In another aspect of the present disclosure, a method of fabricating an oxide-confined semiconductor laser having high aluminum content is provided, as shown in FIG. 1, FIG. 2 and FIG. 3, which includes the following steps.

In S1, the N-type confinement layer 3, the N-type waveguide layer 4, the active region 5, the P-type waveguide layer 6, the P-type confinement layer 7, the P-type high aluminum content layer 8 and the P-type contact layer 9 are epitaxially grown sequentially on the N-type GaAs substrate layer 2.

In S2, a photoresist mask is formed on the P-type contact layer 9.

In S3, the P-type high aluminum content layer 8 and the P-type contact layer 9 are etched using an etching process to form the ridge structure.

In S4, after a removal of the photoresist mask, the P-type high aluminum content layer 8 is oxidized using an oxidation process to form the oxidation confinement layer 81.

In S5, the P-side metal electrode 10 is fabricated on the P-type contact layer 9, and the N-side metal electrode 1 is fabricated below the N-type GaAs substrate layer 2.

In S6, a chip cleavage, a cavity surface coating and a chip packaging are performed to complete a device fabrication.

On the basis of the above-mentioned embodiments, the etching process in S3 includes wet etching and dry etching. In S2 and S3, the P-type high aluminum content layer 8 and the P-type contact layer 9 of the oxide-confined semiconductor laser having high aluminum content are formed into a ridge structure through a photolithography and an etching process, specifically wet etching and dry etching, and the P-type contact layer 9 and the P-type high aluminum content layer 8 on both sides of the ridge structure are etched away, where a width of the ridge is in a range of 1 μm to 1000 μm. In addition, in S6, a front cavity surface of the oxide-confined semiconductor laser having high aluminum content is coated with an anti-reflection film having a reflectivity less than or equal to 50%, and a rear cavity surface of the oxide-confined semiconductor laser having high aluminum content is coated with a high-reflection film having a reflectivity greater than or equal to 80%.

On the basis of the above-mentioned embodiments, the oxidation process in S4 is a wet oxidation process. The oxide-confined semiconductor laser having high aluminum content is formed through S4 and S5. After the oxidation process, a boundary portion of the P-type high aluminum content layer 8 is oxidized to form an oxidation confinement layer 81. The oxidation confinement layer 81 is located between the upper surface of the P-type confinement layer 7 and the lower surface of the P-type contact layer 9, and covers both sides of the ridge structure, so as to form a current injection channel below the ridge structure and an electrical isolation on both sides of the ridge structure. The oxidation confinement layer 81 is formed by oxidizing AlₓGaAs (0.8≤x≤1) in the P-type high aluminum content layer 8 to Al₂O₃. The oxidation process is a wet oxidation process, and a lateral oxidation depth is controlled through an oxidation time. The P-side metal electrode 10 and the N-side metal electrode 1 are respectively fabricated on the P-type contact layer 9 and below the N-type GaAs substrate layer 2 using thermal evaporation or magnetron sputtering method. S5 may further include thinning the epitaxial wafer. In this embodiment, the thickness of the epitaxial wafer is reduced to 120 μm to 150 μm.

On the basis of the above-mentioned embodiments, the electrical injection window and the electrical isolation are simultaneously formed in S4.

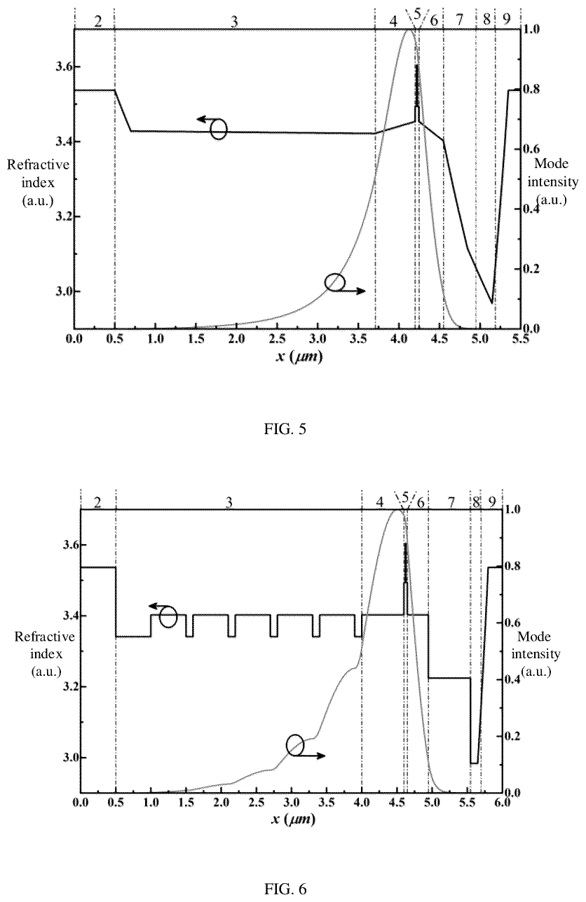

On the basis of the above-mentioned embodiments, referring to FIG. 4, FIG. 5 and FIG. 6, a refractive index distribution and a fundamental mode field distribution of each layer of the oxide-confined semiconductor laser having high aluminum content in the embodiments of the present disclosure may be observed, where a horizontal axis represents a position in an epitaxial direction x, in units of μm; a left vertical axis represents a size of refractive index, a right vertical axis represents a normalized size of light field, and a range of each layer is divided on an upper axis. It may be seen that each of the N-type confinement layer 3, the N-type waveguide layer 4, the P-type waveguide layer 6 and the P-type confinement layer 7 may be made of a single material (having a fixed refractive index, as shown in FIG. 4), or gradually changing materials (having linearly changing refractive indexes, as shown in FIG. 5), or a variety of periodically or quasi-periodically distributed materials (having periodically or quasi-periodically changing refractive indexes, as shown in FIG. 6). The most commonly used material for each of the N-type confinement layer 3, the N-type waveguide layer 4, the P-type waveguide layer 6 and the P-type confinement layer 7 is AlₓGaAs, where each of the N-type confinement layer 3, the N-type waveguide layer 4, the P-type waveguide layer 6 and the P-type confinement layer 7 has a uniform Al content, an Al content gradually varying from 5% to 80%, or an Al content varying periodically. A material having a refractive index greater than or equal to 3.06 (Al content is greater than or equal to 0.8) in an upper layer (i.e., a right side of the P-type confinement layer 7 in FIG. 4, FIG. 5 and FIG. 6) of the P-type confinement layer 7 is divided as the P-type high aluminum content layer 8. A material of the P-type high aluminum content layer 8 may be single or gradually changes. If the P-type high aluminum content layer is thick, an optimal choice is to adopt a gradually changing structure, as shown in FIG. 5 for the P-type high-aluminum content layer 8, to reduce a generation of stress. The P-type contact layer 9 is generally made of GaAs. In the present disclosure, due to a large band gap difference between the AlGaAs material of the P-type high aluminum content layer 8 and the GaAs material, a carrier injection may be affected. Therefore, in the embodiments of the present disclosure, the material of the P-type contact layer 9 gradually changes in the x-direction (epitaxial direction). A starting point of the gradual change is consistent with an end point of the P-type high aluminum content layer 8 in the x-direction, and an end point of the gradual change is the GaAs material. In order to form an ohmic contact, a doping concentration of the P-type contact layer 9 in the embodiments of the present disclosure is greater than 8E18 cm⁻¹.

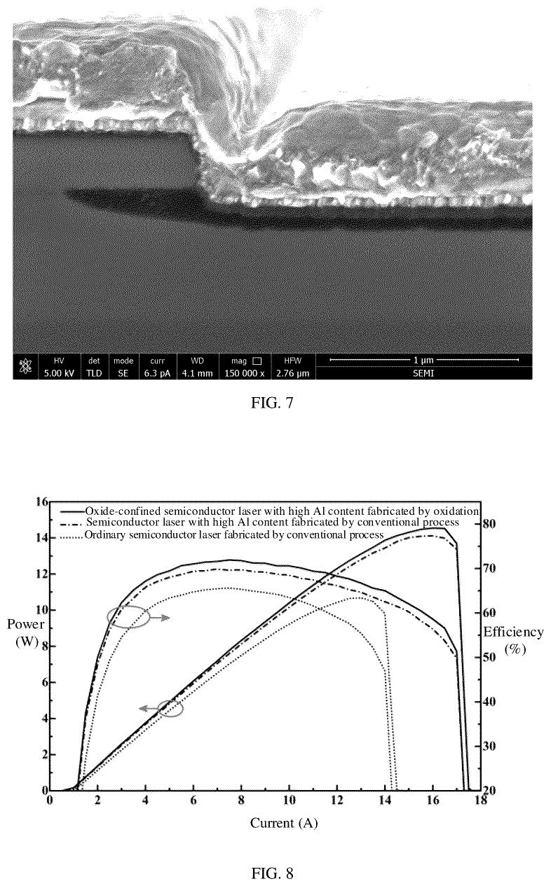

Referring to FIG. 7, it may be seen that the high aluminum content layer below the ridge structure has different inward oxidation depths at different positions. This is because the higher the aluminum content, the easier the material is to be oxidized, and the faster the oxidation rate. Therefore, in FIG. 7, a morphology of the high aluminum content layer after oxidization below the ridge structure is consistent with a change trend of the refractive index of the P-type high aluminum content layer 8 in FIG. 5. In addition, it may be seen that a downward oxidation depth is less than a lateral oxidation depth, which is also related to the different oxidation rates of different aluminum contents.

Referring to FIG. 8, a device performance comparison of an oxide-confined semiconductor laser having high aluminum content fabricated by an oxidation process according to the embodiments of the present disclosure, a semiconductor laser having high aluminum content fabricated by a conventional process and an ordinary semiconductor laser fabricated by a conventional process is shown, where a horizontal axis represents a laser current value with units of A, a left vertical axis represents a laser output light power with units of W, and a right vertical axis represents an electro-optical conversion efficiency of the semiconductor laser with units of %. A solid line represents a performance curve of the oxide-confined semiconductor laser having high aluminum content fabricated by the method of the present disclosure, a dash-dotted line represents a performance curve of the semiconductor laser having high aluminum content fabricated by a conventional process, and a dotted line represents a performance curve of the ordinary semiconductor laser fabricated by a conventional process. It may be seen that the semiconductor lasers having high aluminum content have significant improvements in power and efficiency compared with the ordinary semiconductor laser, and the oxide-confined semiconductor laser fabricated by the oxidation process may have further improvements in performance.

In the oxide-confined semiconductor laser having high aluminum content and the method of fabricating the same according to the above-mentioned embodiments of the present disclosure, the P-type high aluminum content layer 8 is introduced to compensate for the confinement of the P-type confinement layer 7 on the P-side light field, which may help reduce the thickness of the P-side confinement layer 7 without changing the optical confinement factor and the light field distribution, so that the light loss and series resistance of the semiconductor laser may be reduced, the heat dissipation may be improved, and the power and efficiency of the laser may be improved. The introduction of the P-type high aluminum content layer 8 may simplify the fabrication process of the semiconductor laser, and eliminate the need for secondary photolithography and additional growth of insulating material. The fabrication of the oxide-confined semiconductor laser having high aluminum content only requires one photolithography, and the electrical injection window is formed by the oxidation process instead of the insulating layer growth and secondary photolithography in the conventional process. In addition, consumables in the oxidation process are mainly water vapor and nitrogen with low cost.

In summary, the oxide-confined semiconductor laser having high aluminum content provided in the embodiments of the present disclosure has better performance than traditional lasers, and the method of fabricating the oxide-confined laser having high aluminum content provided in the present disclosure has low process difficulty and is easier than traditional methods, so that a yield in the device fabrication process may be improved, consumables in the fabrication process may be reduced, and production costs may be saved.

The specific embodiments described above provide further detailed explanations of the objectives, technical solutions and beneficial effects of the present disclosure. It should be understood that the above are just specific embodiments of the present disclosure and are not intended to limit the present disclosure. Any modifications, equivalent substitutions, improvements, etc. made within the spirit and principles of the present disclosure should be included within the scope of protection of the present disclosure.

1. An oxide-confined semiconductor laser having high aluminum content, sequentially comprising, from bottom to top:
an N-side metal electrode, an N-type GaAs substrate, an N-type confinement layer, an N-type waveguide layer, an active region, a P-type waveguide layer, a P-type confinement layer, a P-type high aluminum content layer, a P-type contact layer, and a P-side metal electrode,
wherein the P-type high aluminum content layer and the P-type contact layer are etched to form a ridge structure;
wherein the P-type high aluminum content layer is oxidized to form an oxidation confinement layer; and
wherein the oxidation confinement layer is located between an upper surface of the P-type confinement layer and a lower surface of the P-type contact layer, and covers both sides of the ridge structure, so as to form a current injection channel below the ridge structure and an electrical isolation on the both sides of the ridge structure.

2. The oxide-confined semiconductor laser having high aluminum content according to claim 1, wherein the P-type high aluminum content layer is made of AlₓGaAs, and 0.8≤x≤1.

3. The oxide-confined semiconductor laser having high aluminum content according to claim 1, wherein the oxidation confinement layer is made of Al₂O₃.

4. The oxide-confined semiconductor laser having high aluminum content according to claim 1, wherein a width of the ridge structure is in a range of 1 μm to 1000 μm.

5. The oxide-confined semiconductor laser having high aluminum content according to claim 1, wherein a thickness of the P-type high aluminum content layer is in a range of 10 nm to 500 nm.

6. The oxide-confined semiconductor laser having high aluminum content according to claim 1, wherein a P-type doping concentration in the P-type high aluminum content layer is in a range of 1E17 cm⁻³ to 1E20 cm⁻³.

7. The oxide-confined semiconductor laser having high aluminum content according to claim 1, wherein a front cavity surface of the oxide-confined semiconductor laser having high aluminum content is coated with an anti-reflection film having a reflectivity less than or equal to 50%, and a rear cavity surface of the oxide-confined semiconductor laser having high aluminum content is coated with a high-reflection film having a reflectivity greater than or equal to 80%.

8. The oxide-confined semiconductor laser having high aluminum content according to claim 1, wherein the active region comprises a quantum well, a quantum dot, or a superlattice structure.

9. The oxide-confined semiconductor laser having high aluminum content according to claim 1, wherein each of the N-type confinement layer, the N-type waveguide layer, the P-type waveguide layer and the P-type confinement layer is made of Al GaAs; and
wherein each of the N-type confinement layer, the N-type waveguide layer, the P-type waveguide layer and the P-type confinement layer has a uniform Al content, an Al content gradually varying from 5% to 80%, or an Al content varying periodically.

10. A method of fabricating an oxide-confined semiconductor laser having high aluminum content, applied to the oxide-confined semiconductor laser having high aluminum content of claim 1, wherein the method comprises:
epitaxially growing, on the N-type GaAs substrate layer, the N-type confinement layer, the N-type waveguide layer, the active region, the P-type waveguide layer, the P-type confinement layer, the P-type high aluminum content layer and the P-type contact layer sequentially;
forming a photoresist mask on the P-type contact layer;
etching the P-type high aluminum content layer and the P-type contact layer using an etching process to form the ridge structure;
oxidizing, after removing the photoresist mask, the P-type high aluminum content layer using an oxidation process to form the oxidation confinement layer;
fabricating the P-side metal electrode on the P-type contact layer, and fabricating the N-side metal electrode below the N-type GaAs substrate layer; and
performing a chip cleavage, a cavity surface coating and a chip packaging to complete a device fabrication.
